(19) United States
(12) Patent Application Publication
(10) Pub. No.: US 2017/0005236 A1
(43) Pub. Date: Jan. 5, 2017

(54) LIGHT EMITTING DIODE PACKAGE AND LIGHT EMITTING DIODE MODULE

(71) Applicant: Genesis Photonics Inc., Tainan City (TW)

(72) Inventors: Jing-En Huang, Tainan City (TW); Shao-Ying Ting, Tainan City (TW); Po-Jen Su, Taipei City (TW); Chih-Ling Wu, New Taipei City (TW); Yi-Ru Huang, Tainan City (TW); Yu-Yun Lo, Tainan City (TW)

(73) Assignee: Genesis Photonics Inc., Tainan City (TW)

(21) Appl. No.: 15/264,564

(22) Filed: Sep. 13, 2016

Related U.S. Application Data
(62) Division of application No. 14/583,210, filed on Dec. 26, 2014.

(30) Foreign Application Priority Data
Dec. 26, 2013 (TW) 102148482
Oct. 13, 2014 (TW) 103135425

(51) Int. Cl. H01L 33/50; H01L 25/075; H01L 33/54; H01L 33/48; H01L 33/60; H01L 33/56

(52) U.S. Cl. CPC H01L 33/502; H01L 33/60; H01L 33/56; H01L 33/54; H01L 33/486; H01L 25/0753; H01L 2933/0033

(57) ABSTRACT

A light emitting diode (LED) package includes at least one light emitting unit having a first electrode and a second electrode, a first molding compound covering a part of the light emitting unit to expose the first electrode and the second electrode, and a first light transmissive plate disposed on the first molding compound opposite the light emitting unit. A side surface of the first molding compound and a side surface of the first light transmissive plate are coplanar or have even adjoined edges.

### CROSS-REFERENCE TO RELATED APPLICATION

This application is a divisional application of and claims the priority benefit of a previous application Ser. No. 14/583,210, filed on Dec. 26, 2014, now pending, which claims the priority benefits of Taiwan application serial no. 102148482, filed on Dec. 26, 2013 and Taiwan application serial no. 103135425, filed on Oct. 13, 2014. The entirety of each of the above-mentioned patent applications is hereby incorporated by reference herein and made a part of this specification.

### BACKGROUND OF THE INVENTION

1. Field of the Invention

The disclosure relates to a light emitting diode package and a light emitting diode module and, more particularly, to a light emitting diode package and a light emitting diode module using package technology without a package substrate.

2. Description of Related Art

Referring to FIG. 1, FIG. 1 is a schematic view illustrating a light emitting diode package 1 of the prior art. As shown in FIG. 1, the light emitting diode package includes a package substrate 10, a light emitting diode chip 12 and a molding compound 14. The light emitting diode chip 12 is disposed on the package substrate 10 and the molding compound is dispensed on the package substrate 10 and the light emitting diode chip 12, so as to package the light emitting diode chip 12. That is to say, the light emitting diode chip 12 is located between the package substrate 10 and the molding compound 14. Since the light emitting diode chip 12 has to be disposed on the package substrate 10 before the light emitting diode chip 12 is packaged by the molding compound 14, the manufacture process is inconvenient and the capacity cannot be improved.

### SUMMARY OF THE INVENTION

The disclosure provides a light emitting diode package and a light emitting diode module using package technology without a package substrate.

According to one embodiment of the disclosure, a light emitting diode package comprises at least one light emitting unit having a first electrode and a second electrode, a first molding compound covering a part of the light emitting unit to expose the first electrode and the second electrode, and a first light transmissive plate disposed on the first molding compound opposite the light emitting unit, wherein a side surface of the first molding compound and a side surface of the first light transmissive plate are coplanar or have even adjoined edges.

According to one embodiment of the disclosure, the light emitting diode package comprises at least one light emitting unit having a first electrode and a second electrode, a first molding compound covering a part of the light emitting unit to expose the first electrode and the second electrode, a first light transmissive plate disposed on the first molding compound opposite the light emitting unit, a second light transmissive plate disposed on the first transmissive plate, and a second molding compound disposed between the first light transmissive plate and the second light transmissive plate. The second molding compound covers the first light transmissive plate and a part of the first molding compound to expose the first electrode and the second electrode, and a side surface of the second molding compound and a side surface of the second light transmissive plate are coplanar or have even adjoined edges.

According to one embodiment of the disclosure, the light emitting diode module comprises a support base and a light emitting diode package of claim 1 disposed on the support base and electrically connected to the support base.

According to one embodiment of the disclosure, the light emitting diode module comprises a support base and a light emitting diode package of claim 11 disposed on the support base and electrically connected to the support base.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a light emitting diode package of the prior art.

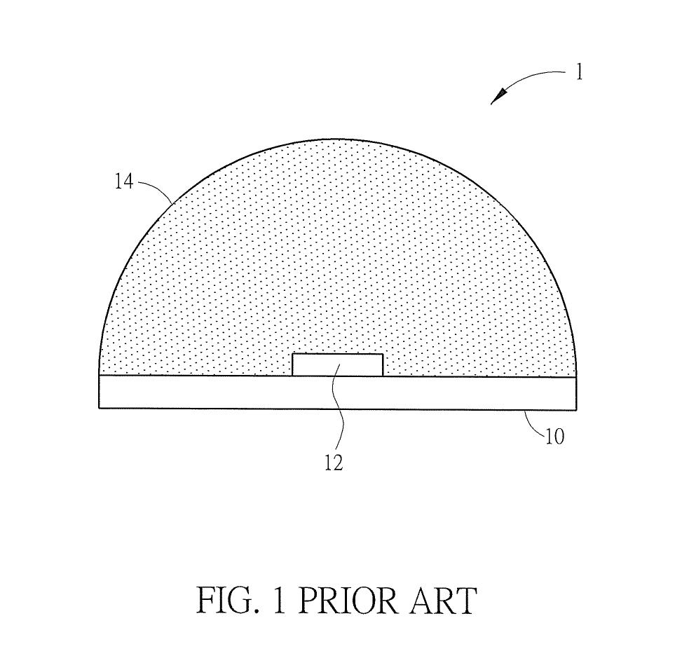

FIG. 2 is a schematic view illustrating a light emitting diode package according to a first embodiment of the disclosure.

FIG. 3 is a schematic view illustrating a plurality of light emitting units packaged by the first molding compound and the first transparent.

FIG. 4 is a schematic view illustrating a light emitting diode package according to a second embodiment of the disclosure.

FIG. 5 is a schematic view illustrating a light emitting diode package according to a third embodiment of the disclosure.

FIG. 6 is a schematic view illustrating a light emitting diode package according to a fourth embodiment of the disclosure.

FIG. 7 is a schematic view illustrating a light emitting diode package according to a fifth embodiment of the disclosure.

FIG. 8 is a schematic view illustrating a light emitting diode package according to a sixth embodiment of the disclosure.

FIG. 9 is a schematic view illustrating a light emitting diode module according to a seventh embodiment of the disclosure.

FIG. 10 is a schematic view illustrating a light emitting diode module according to an eighth embodiment of the disclosure.

FIG. 11 is a schematic view illustrating a light emitting diode package according to a ninth embodiment of the disclosure.

FIG. 12 is a schematic view illustrating a light emitting diode module according to a tenth embodiment of the disclosure.

### DESCRIPTION OF THE EMBODIMENTS

It should be noted that in the following embodiments of the disclosure, the elements having identical or similar functions are denoted by the same numerals, therefore the redundant descriptions for those elements in different embodiments would not be repeated.

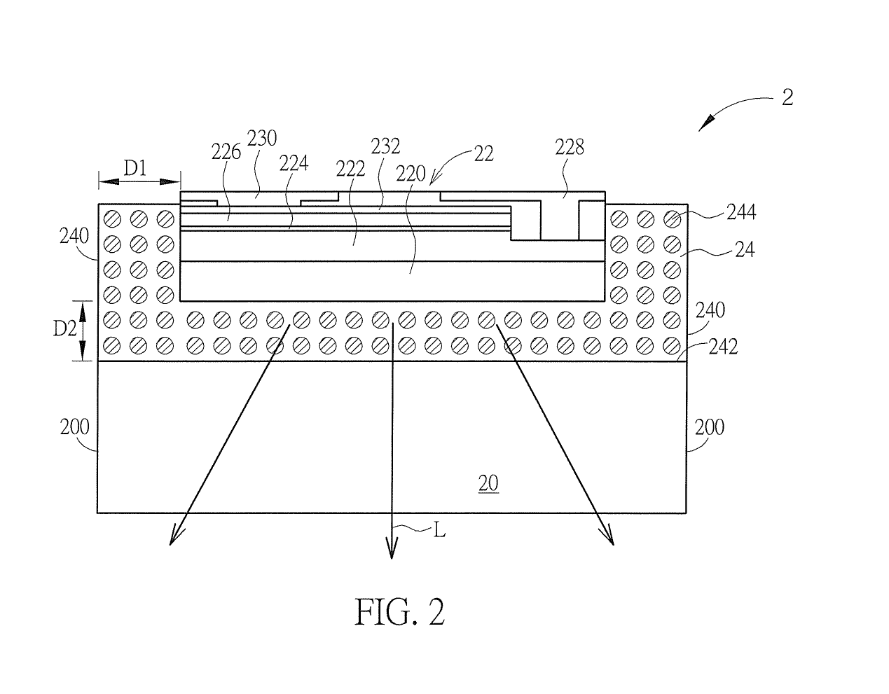

FIG. 2 illustrates the first embodiment of the disclosure. As shown in FIG. 2, the light emitting diode (LED) package 2 includes a first light transmissive plate 20, a light emitting unit 22 and a first molding compound 24. The light emitting unit 22 is disposed on the first light transmissive plate 20, and the first molding compound 24 is disposed between the light emitting unit 22 and the first light transmissive plate 20 and covers a part of the light emitting unit 22.

In this embodiment, the light emitting unit 22 includes a first type semiconductor layer 222 located on a substrate 220, a light emitting layer 224 located on the first type semiconductor layer 222, a second type semiconductor layer 226 located on the light emitting layer 224, a reflective layer 232 located on the second type semiconductor layer 226, a first electrode 228 electrically connected to the first type semiconductor layer 222, a second electrode 230 electrically connected to the second type semiconductor layer 226, and the first electrode 228 and the second electrode 230 being exposed by the first molding compound 24. The light emitting unit 22 may be, but not limited to, a flip-chip LED chip and the material of the substrate 220 may be, but not limited to, sapphire. In other words, the first molding compound 24 does not cover the first electrode 228 and the second electrode 230 of the light emitting unit 22. The first type semiconductor layer 222 may be an N-type semiconductor layer (e.g. N-type GaN layer) and the second type semiconductor layer 226 may be a P-type semiconductor layer (e.g. P-type GaN layer). In the meantime, the first electrode 228 may be an N electrode and the second electrode 230 may be a P electrode.

The reflectivity of the reflective layer 232 may be larger than 90% and the material of the reflective layer 232 may be selected from a group essentially consisting of, but not limited to, Au, Ag, Al, Cu, Ni and Cr, therefore the light emitting efficiency of the light emitting unit 22 can be enhanced. It should be noted whether a reflective layer is needed to be disposed in the light emitting unit or not depends on the practical light emitting requirements.

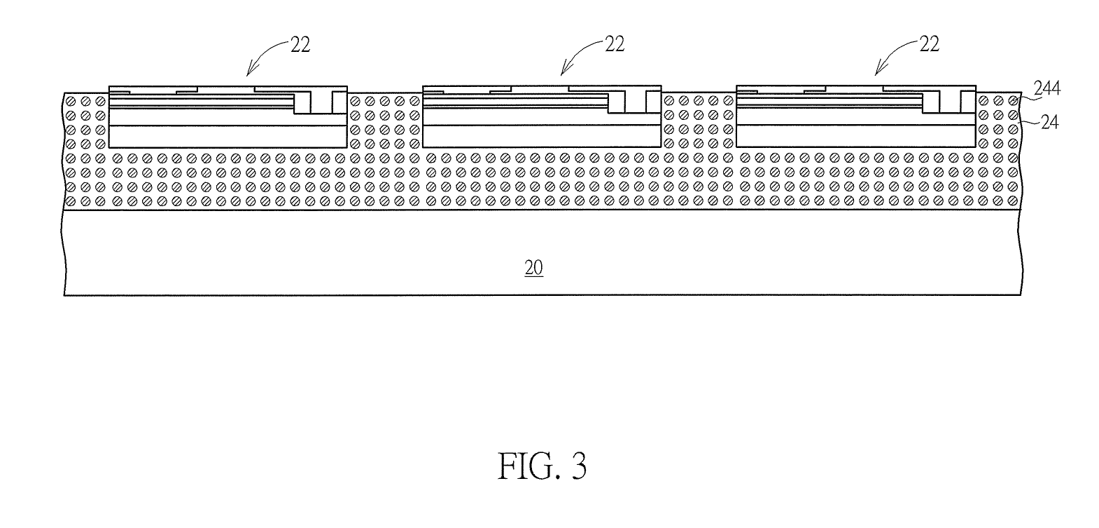

FIG. 3 is a schematic view illustrating a plurality of light emitting units 22 packaged by the first molding compound 24 and the first transparent 20. As shown in FIG. 3, a plurality of light emitting units 22 are directly packaged by the first molding compound 24 and then the first light transmissive plate 20 is used to shape the first molding compound 24. Afterward, a cutting process for cutting the first molding compound 24 and the first light transmissive plate 20 is performed to form the individual LED packages 2 shown in FIG. 2, wherein each of the LED packages 2 contains a single light emitting unit 22. Therefore, the LED packages 2 without package substrate is produced. In the LED package 2, a side surface 240 of the first molding compound 24 and a side surface 200 of the first light transmissive plate 20 are coplanar or have even adjoined edges. Since the light emitting unit 22 is packaged without using the package substrate, the manufacture process of the LED package 2 according to the disclosure is convenient and the production capacity can be improved effectively. Furthermore, in the disclosure, the first light transmissive plate 20 is utilized to shape the first molding compound 24 without using additional molds, such that the manufacture cost can also be reduced.

As shown in FIG. 2, when the light emitting unit 22 emits light L, at least a portion of light L passes through the first molding compound 24 and the first light transmissive plate 20 in sequence and is emitted out of the LED package 2. In this embodiment, the light transmittance of the first light transmissive plate 20 for the light L emitted from the light emitting unit 22 may be larger than, but not limited to, 90% and the material of the first light transmissive plate 20 may be, but not limited to, glass or ceramic. According to the light pattern generated by the light emitting unit 22, a distance D1 between the light emitting unit 22 and the side surface 240 of the first molding compound 24 may be larger than a distance D2 between the light emitting unit 22 and a bottom surface 242 of the first molding compound 24, therefore the light emitting efficiency and the light emitting angle of the light emitting unit 22 can be enhanced, in which the first light transmissive plate 20 is disposed on the bottom surface 242 of the first molding compound 24.

In this embodiment, the first molding compound 24 may contain first phosphor particles 244. Emission peak wavelengths of the first phosphor particles 244 are larger than those of the light emitting unit 22. The first phosphor particles 244 can convert at least portions of the light L in shorter wavelengths emitted by the light emitting unit 22 into longer wavelengths, therefore the light color of the LED package 2 is changed. The distance D1 between the light emitting unit 22 and the side surface 240 of the first molding compound 24 may be larger than the distance D2 between the light emitting unit 22 and the bottom surface 242 of the first molding compound 24, such that the LED package can have better light uniformity and light intensity. It should be noted that it is depends on practical light emitting requirements for whether first phosphor particles are needed to be dispersed into the first molding compound or not.

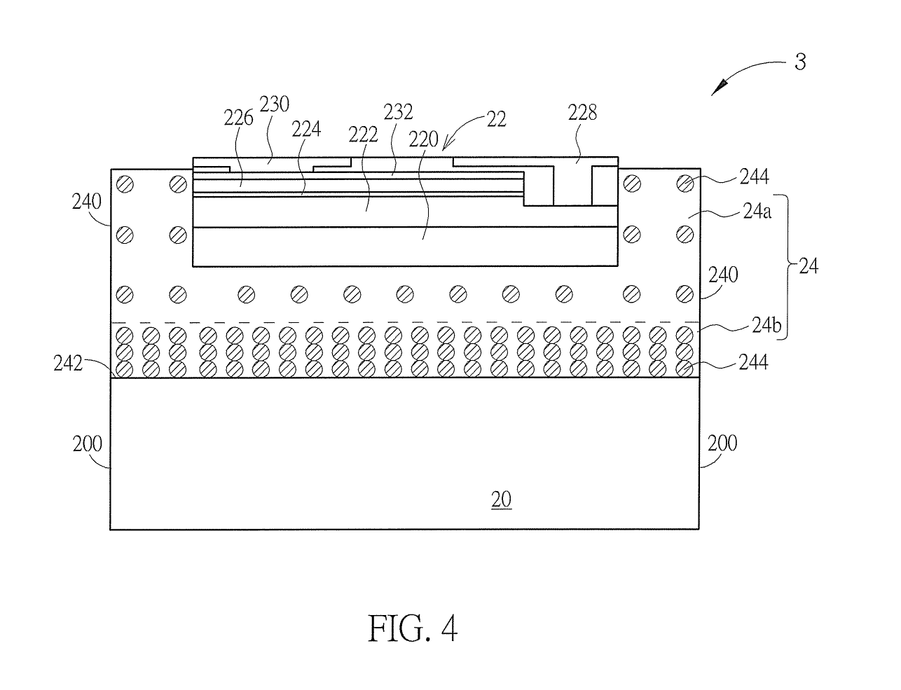

FIG. 4 illustrates the second embodiment of the disclosure. Referring to FIG. 4 along with FIG. 2, one of the differences between the LED packages 3 and 2 is that the first molding compound 24 of the LED package 3 includes a first portion 24a and a second portion 24b, and the first portion 24a is located between the light emitting unit 22 and a second portion 24b, and the concentration of the first phosphor particles 244 in the first portion 24a is smaller than that in the second portion 24b. Accordingly, the light emitting efficiency of the light emitting unit 22 can be further enhanced.

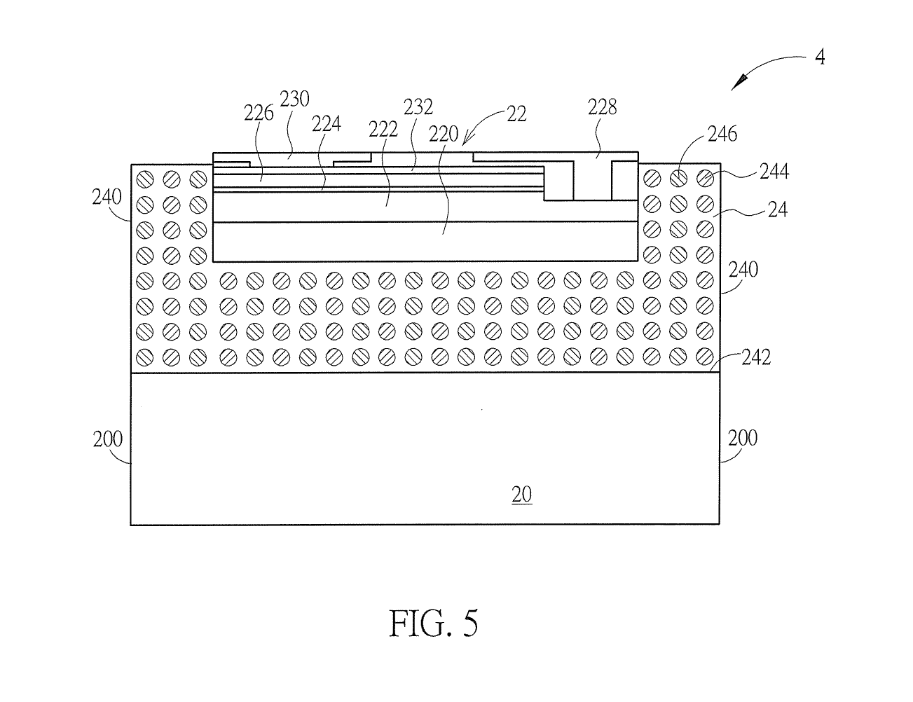

FIG. 5 illustrates the third embodiment of the disclosure. Referring to FIG. 5 along with FIG. 2, one of the differences between the LED packages 4 and 2 is that the first molding compound 24 further contains second phosphor particles 246. In this embodiment, the emission peak wavelengths of the first phosphor particles 244 may be smaller than those of the second phosphor particles 246. That is to say, the first phosphor particles 244 and the second phosphor particles 246 are used to convert at least portions of the light L in shorter wavelengths emitted by the light emitting unit 22 into two different and longer wavelengths, therefore the light color of the LED package 3 is changed. When the lights emitted from the first phosphor particles 244 and the second phosphor particles 246 are mixed with the remaining portions of the light L ted by the light emitting unit 22, the color saturation of the LED package 4 can be enhanced.

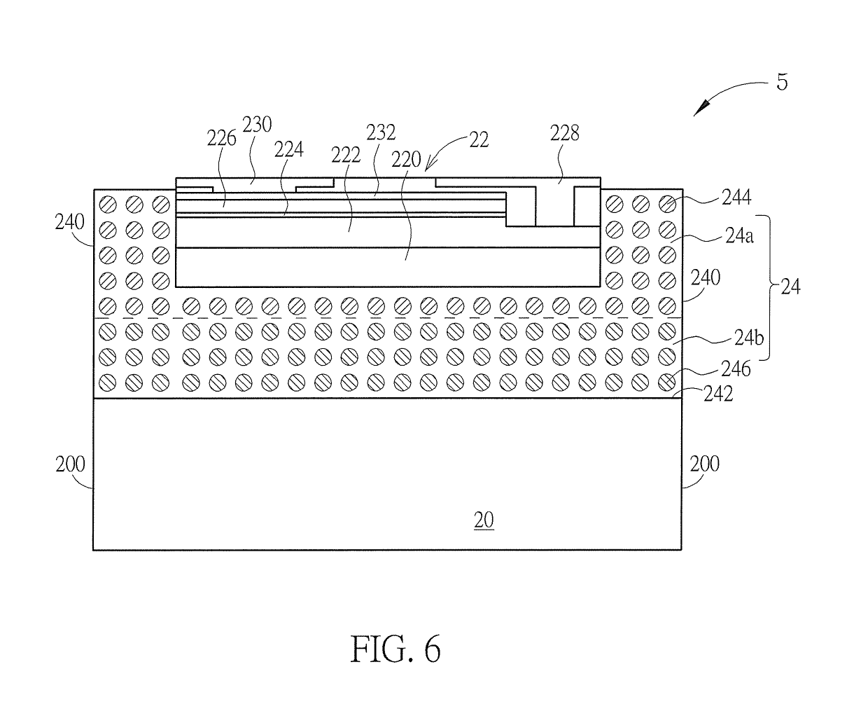

FIG. 6 illustrates the fourth embodiment of the disclosure. Referring to FIG. 6 along with FIG. 2, one of the differences between the LED packages 5 and 2 is that the first molding compound 24 of the LED package 5 includes a first portion 24a and a second portion 24b, and first phosphor particles 244 and second phosphor particles 246 dispersed in the first portion 24a and the second portion 24b respectively. In this embodiment, emission peak wavelengths of the first phosphor particles 244 and the second phosphor particles 246 are larger than those of the light emitting unit 22, and the emission peak wavelengths of the first phosphor particles 244 may be smaller than those of the second phosphor particles 246. It could have a better conversion efficiency for phosphors when the difference between the absorption wavelengths of the first phosphor particles 244 and the emission peak wavelengths of the light emitting unit 22 are smaller than 150 nm, and the difference between the absorption wavelengths of the second phosphor particles 246 and the emission peak wavelengths of the first phosphor particles 244 are smaller than 150 nm.

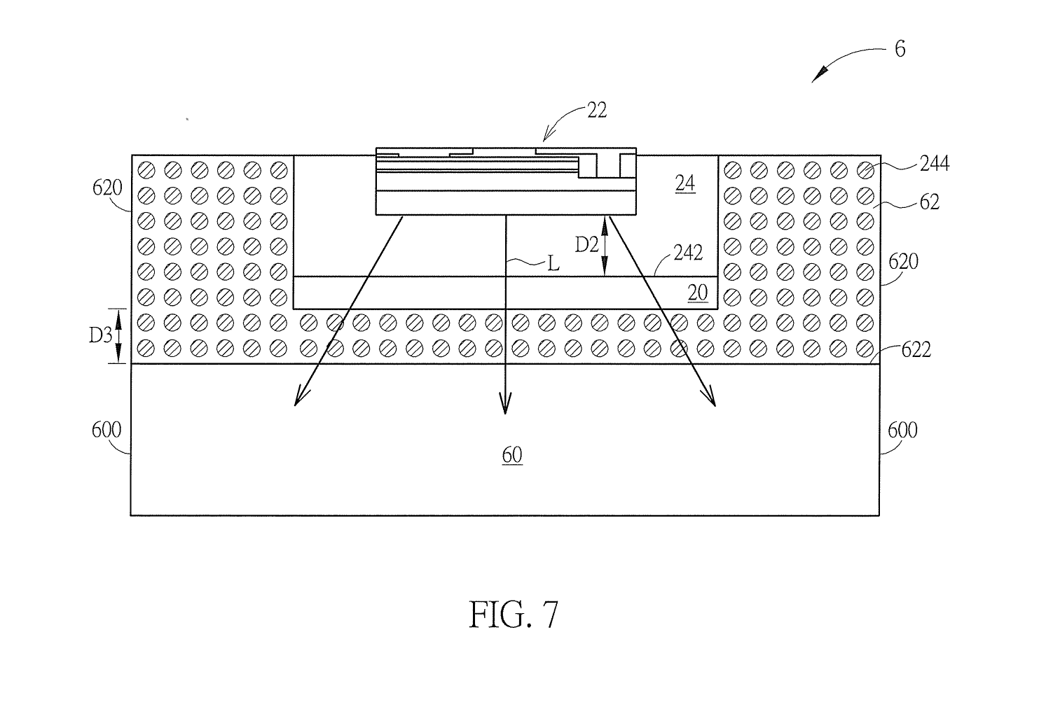

FIG. 7 illustrates the fifth embodiment of the disclosure. Referring to FIG. 7 along with FIG. 2, one of the differences between the LED packages 6 and 2 is that the LED package 6 further includes a second light transmissive plate 60 and a second molding compound 62 covering the first light transmissive plate 20 and a part of the first molding compound 24 and containing first phosphor particles 244, and the first molding compound 24 does not contain phosphor particles. In other embodiments, the first molding compound 24 may contain phosphor particles. As shown in FIG. 7, the second light transmissive plate 60 is disposed on a bottom surface 622 of the second molding compound 62, and a side surface 620 of the second molding compound 62 and a side surface 600 of the second light transmissive plate 60 may be coplanar or have even adjoined edges. In this embodiment, emission peak wavelengths of the first phosphor particles 244 are larger than those of the light emitting unit 22, and the size of the first phosphor particles 244 may be between 3 μm and 50 μm. Furthermore, the distance D2 (from the light emitting unit 22 to the bottom surface 242 of the first molding compound 24) is about 1 to 30 times of the distance D3 (from the first light transmissive plate 20 to the bottom surface 622 of the second molding compound 62). The light L for exciting the first phosphor particles 244 might pass through the first molding compound 24 and the first light transmissive plate 20, therefore when the thickness ratio of the first molding compound 24 to the second molding compound 62 falls within the above-mentioned range, a better light extraction effect can be obtained and more amount of the light L can be extracted for exciting the first phosphor particles 244. By utilizing the aforementioned configuration, the whole light emitting efficiency can be further enhanced and different light emitting effects can be obtained.

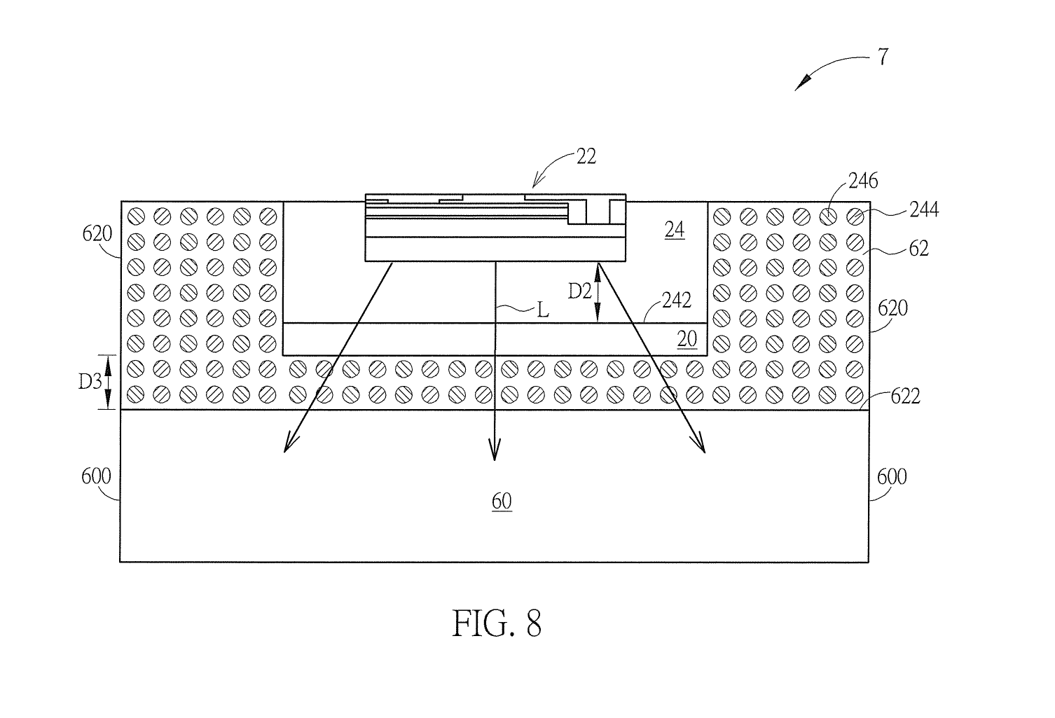

FIG. 8 illustrates the sixth embodiment of the disclosure. Referring to FIG. 8 along with FIG. 7, one of the differences between the LED packages 7 and 6 is that the second molding compound 62 of the LED package 7 further contains second phosphor particles 246. Though the first molding compound 24 does not contain phosphor particles, but in other embodiments, the first molding compound 24 may contain phosphor particles. In this embodiment, the emission peak wavelengths of the second phosphor particles 246 may be larger than those of the first phosphor particles 244. The first phosphor particles 244 and the second phosphor particles 246 are used to convert at least portions of the light L in shorter wavelengths emitted by the light emitting unit 22 into two different and longer wavelengths, therefore the light color of the LED packages 7 is changed. When the lights emitted from the first phosphor particles 244 and the second phosphor particles 246 are mixed with the remaining portions of the light L emitted from the light emitting unit 22, the color saturation of the LED package 7 can be enhanced.

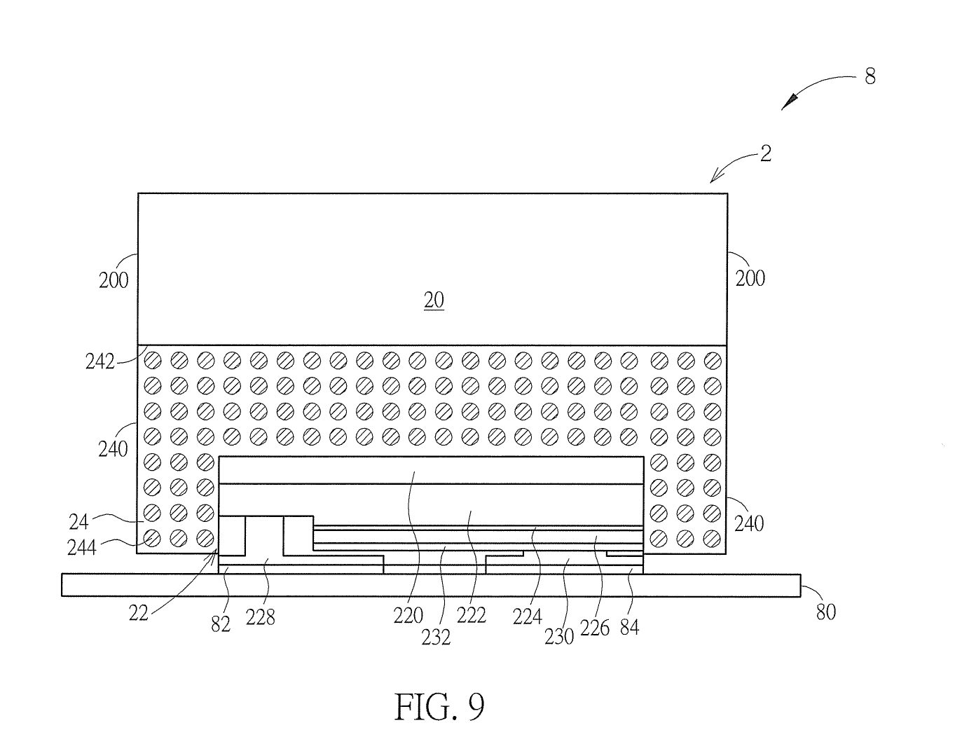

FIG. 9 illustrates a light emitting diode (LED) module 8 according to a seventh embodiment of the disclosure. Referring to FIG. 9 along with FIG. 2, the LED module 8 includes a support base 80 and a LED package 2 disposed on thereon. A first bonding pad 82 and a second bonding pad 84 are disposed on the support base 80 and electrically connected to the LED package 2. In this embodiment, the first bonding pad 82 may be an N bonding pad and the second bonding pad 84 may be a P bonding pad. As shown in FIG. 9, the first electrode 228 and the second electrode 230 of the light emitting unit 22 are electrically connected to the first bonding pad 82 and the second bonding pad 84 respectively. The support base 80 may be, but not limited to, a flexible circuit board, and may be used as, but not limited to, a lamp socket in various shapes. Furthermore, the LED package 2 used in the LED module 8 shown in FIG. 9 can be replaced by any of the LED packages described in the above-mentioned embodiments of the disclosure shown in drawings from FIGS. 4 to 8 according to the practical applications.

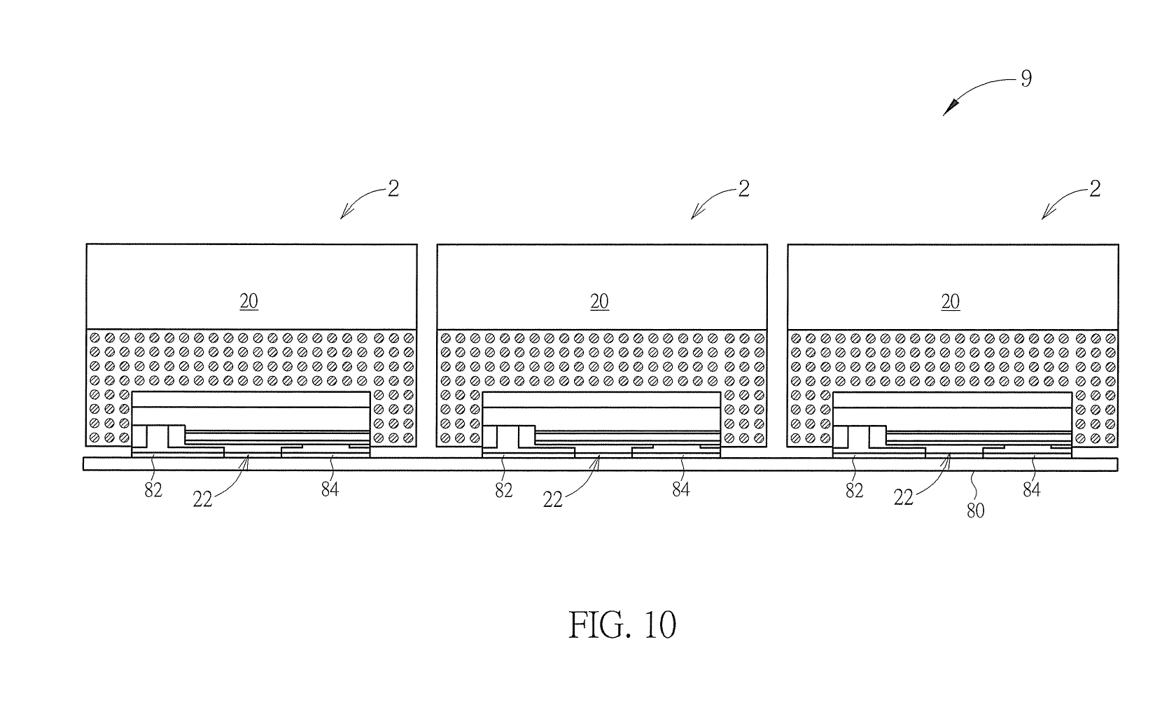

FIG. 10 illustrates an LED module 9 according to an eighth embodiment of the disclosure. Referring to FIG. 10 along with FIG. 9, one of the differences between the LED modules 9 and 8 is that the LED module 9 includes a plurality of LED packages 2. As shown in FIG. 10, a plurality of first bonding pads 82 and second bonding pads 84 are disposed on the support base 80 and electrically connected to the LED packages 2. The amount of LED packages 2 needed to be disposed on the support base 80 would depend on practical light emitting requirements. Furthermore, the LED package 2 shown in FIG. 10 can be replaced by any of the LED packages described in the above-mentioned embodiments of the disclosure shown in drawings from FIGS. 4 to 8 according to the practical applications.

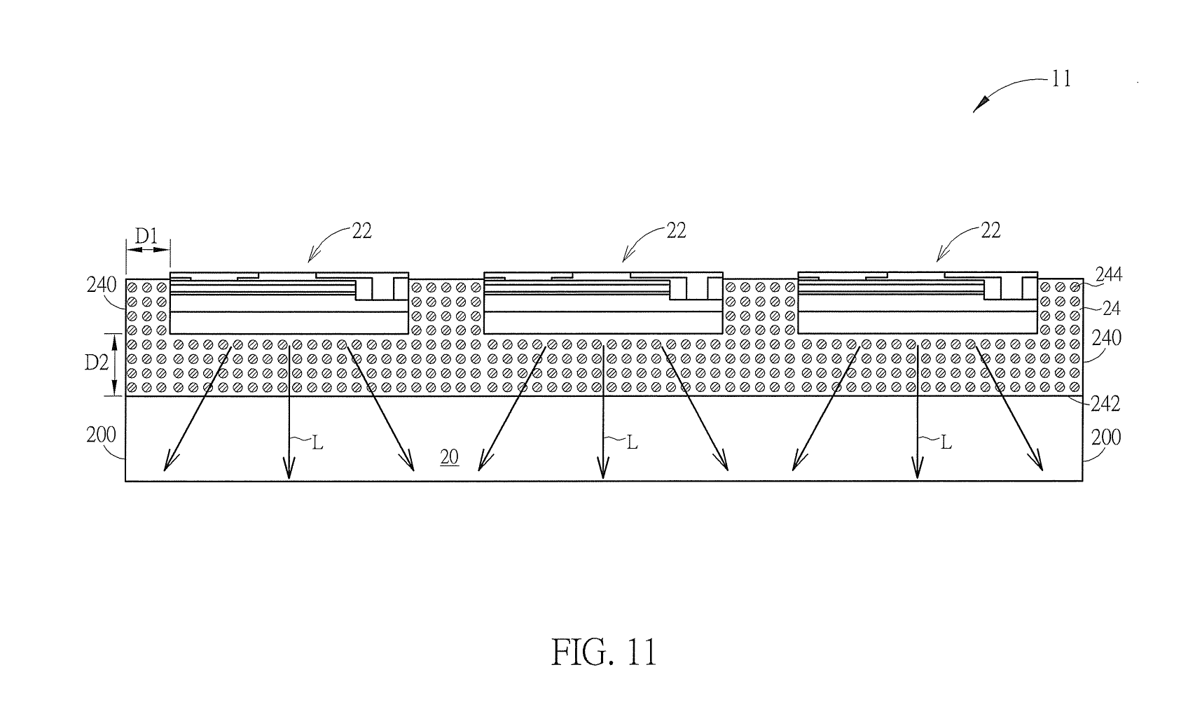

FIG. 11 illustrates an LED package 11 according to a ninth embodiment of the disclosure. As shown in FIG. 3, a plurality of light emitting units 22 are packaged by the first molding compound 24 directly and then use the first light transmissive plate 20 to shape the first molding compound 24. Afterward, a cutting process for cutting the first molding compound 24 and the first light transmissive plate 20 is performed to form the individual LED packages 11 shown in FIG. 11, in which each of the LED packages 11 contains plural light emitting unit 22. Therefore, the LED packages 11 without package substrate is produced. As shown in FIG. 11, the LED package 11 includes three light emitting units 22 after the cutting process. In other embodiment, the LED package 11 may include two, four or more than four light emitting units 22. Furthermore, in the LED package 11 after the cutting process, a side surface 240 of the first molding compound 24 and a side surface 200 of the first light transmissive plate 20 may be coplanar or have even adjoined edges.

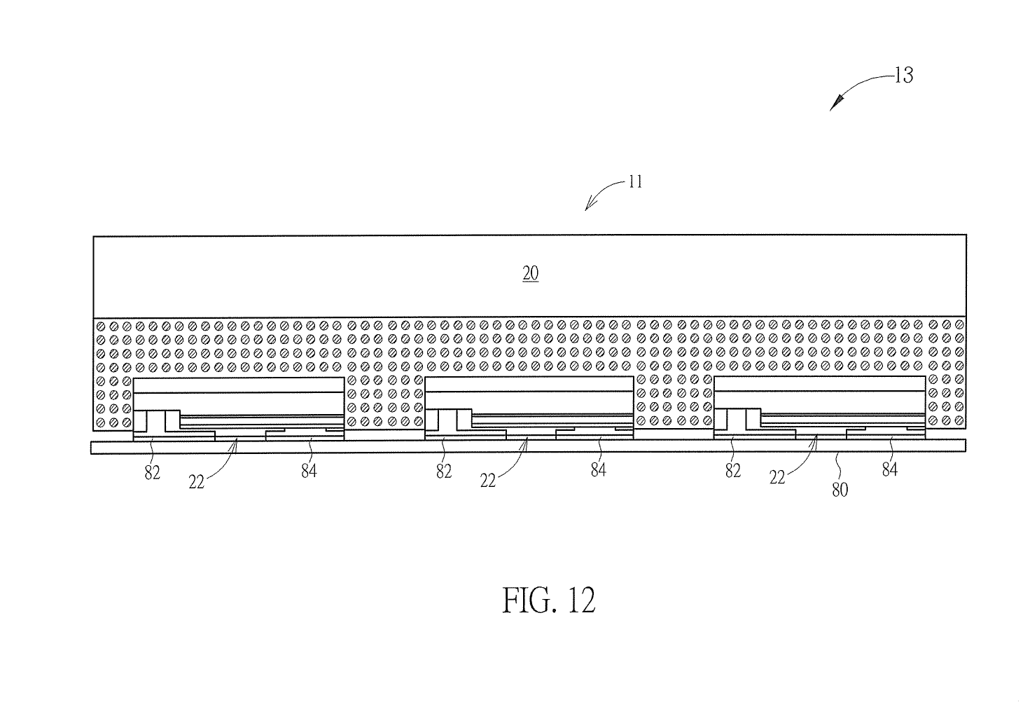

FIG. 12 illustrates an LED module 13 according to a tenth embodiment of the disclosure. Referring to FIG. 12, the LED module 13 includes a support base 80, and a light emitting diode package 11 containing a plurality of light emitting units 22, wherein first bonding pads 82 and second bonding pads 84 are disposed on the support base 80 and electrically connected to the light emitting units 22. Referring to the LED module 9 shown in FIG. 10 and the LED module 13 shown in FIG. 12, choosing the single LED package 11 containing multiple light emitting units 22 or the plurality of LED packages 2 each containing a single light emitting unit 22 to be mounted to the support base 80 depends on the practical applications and light emitting requirements.

As the above mentioned, the molding compound and the light transmissive plate are used to package a plurality of light emitting units directly and then perform a cutting process to form the individual light emitting diode packages. Accordingly, the light emitting unit can be packaged without using a package substrate, it is convenient to the manufacture process of the LED packages and the production capacity can also be improved effectively. In the LED package after the cutting process, the side surface of the molding compound and the side surface of the light transmissive plate may be coplanar or have even adjoined edges. Furthermore, the light transmissive plate is utilized to shape the molding compound without using additional molds, such that the manufacture cost can be reduced.

Because the hardness of the light transmissive plate is larger than that of the molding compound, the light transmissive plate can protect the light emitting unit from damages caused by external influences while the LED packages are disposed onto the support base, and maintain the light emitting capability intact. Moreover, the molding compound described in the disclosure may contain the phosphor particles and by adjusting the concentration and/or the emission wavelength of the phosphor particles, the light emitting efficiency and the light color can be manipulated. Similarly, the light transmissive plate can also protect the phosphor particles coming off from the molding compound. In addition, the light transmissive plate and the molding compound both can extract much more light from the LED packages, therefore the light emitting efficiency is enhanced.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A light emitting diode (LED) package comprising:
at least one light emitting unit having a first electrode and a second electrode;
a first molding compound encapsulating the light emitting unit and at least exposing the first electrode and the second electrode;
a second molding compound comprising a plurality of phosphor particles dispersed therein and covering a part of the first molding compound and at least exposing the first electrode and the second electrode; and
a first light transmissive member disposed on the second molding compound, wherein the second molding compound is disposed between the first light transmissive member and the first molding compound.

2. The LED package of claim 1, further comprising a second light transmissive member disposed between the light emitting unit and the second molding compound.

3. The LED package of claim 2, wherein the second molding compound is disposed between the first light transmissive member and the second light transmissive member.

4. The LED package of claim 2, wherein the second light transmissive member is disposed on the light emitting unit and the first molding compound.

5. The LED package of claim 2, wherein the first molding compound at least encapsulates a lateral surface of the light emitting unit and a surface of the second light transmissive member.

6. The LED package of claim 1, wherein the first molding compound is free of phosphor particles.

7. The LED package of claim 1, wherein the first electrode and the second electrode of the light emitting unit protrude out of a top surface of the first molding compound.

8. The LED package of claim 1, wherein the first electrode and the second electrode of the light emitting unit are coplanar.

9. The LED package of claim 1, wherein the light emitting unit further comprises a substrate, a first type semiconductor layer disposed on the substrate, a light emitting layer disposed on the first type semiconductor layer, and a second type semiconductor layer disposed on the light emitting layer, wherein the first electrode is coupled to the first type semiconductor layer, and the second electrode is coupled to the second type semiconductor layer.

10. The LED package of claim 1, further comprising a support base onto which the first electrode and the second electrode of the light emitting unit are bonded.

11. The LED package of claim 10, wherein the light emitting unit further comprises a first type semiconductor layer, a second type semiconductor layer, and a light emitting layer disposed between the first type semiconductor layer and second type semiconductor layer, wherein the first electrode is coupled to the first type semiconductor layer, and the second electrode is coupled to the second type semiconductor layer.

12. The LED package of claim 1, wherein the second molding compound and the first light transmissive member have coplanar lateral surfaces or have even adjoined edges.
